(19) United States
(12) Patent Application Publication
(10) Pub. No.: US 2011/0088739 A1
(43) Pub. Date: Apr. 21, 2011

(54) HIGH EFFICIENCY THERMOELECTRIC CONVERTER

(75) Inventors: Alfred A. ZINN, Palo Alto, CA (US); Roux M. Heyns, San Francisco, CA (US)

(73) Assignee: LOCKHEED MARTIN CORPORATION, Bethesda, MD (US)

(21) Appl. No.: 12/908,813

(22) Filed: Oct. 20, 2010

Related U.S. Application Data
(60) Provisional application No. 61/253,479, filed on Oct. 20, 2009.

(51) Int. Cl. H01L 35/32; B32B 5/16; B23K 10/00; H01B 1/02; B82Y 30/00

(52) U.S. Cl. 136/205; 428/323; 219/121.59; 252/520.5; 252/521.1; 252/519.5; 977/779

(57) ABSTRACT

A composite includes a matrix having a plurality of matrix nanoparticles and a plurality of hetero-nanoparticles dispersed in the matrix. The hetero-nanoparticles include an atom having an atomic weight larger than the atoms in the matrix nanoparticles. A thermoelectric converter includes one or more first legs, each including an n-doped composite, and one or more second legs, each including a p-doped composite. The n-doped and p-doped composites include a matrix having a plurality of matrix nanoparticles and a plurality of hetero-nanoparticles dispersed in the matrix. The matrix nanoparticles and hetero-nanoparticles in each of the n-doped and p-doped composites can be the same or different. A method of making a composite for thermoelectric converter applications includes providing a mixture a plurality of matrix nanoparticles and a plurality of hetero-nanoparticles and applying current activated pressure assisted densification to form the composite.

This application claims the benefit of U.S. Provisional Patent Application No. 61/253,479, filed on Oct. 20, 2009, which is hereby incorporated by reference herein.

### STATEMENT REGARDING FEDERALLY SPONSORED RESEARCH OR DEVELOPMENT

Not applicable.

### BACKGROUND

The present invention generally relates to thermoelectric converters, and more particularly to high efficiency thermoelectric converters.

Thermoelectric converters provide a technology platform that can reclaim heat energy in a wide range of operating conditions. In principle, thermoelectric conversion can be achieved on quite disparate scales, from as small as personal computer and electronics devices to large scale heat recycle in the context of combustion engine technology. For example, over 60% of the energy in the United States may never be utilized and may be lost as waste heat, with losses in the transportation sector being as high as 80%. Thermoelectric conversion may also be realized on very large scale such as in energy storage applications using large thermal receiver panels on a scale similar to that employed in solar panel technology.

In order to realize the full range of thermoelectric conversion applications, however, there is a need for more efficient thermoelectric conversion. Currently, the state of the art thermoelectric converters operate at only about 5% efficiency. Moreover, there is a need to develop more efficient and scalable composite production processes to tap into large scale applications. The present invention satisfies these needs and provides related advantages as well.

### SUMMARY

In some aspects, embodiments disclosed herein relate to a composite that includes a matrix which includes a plurality of matrix nanoparticles and a plurality of hetero-nanoparticles dispersed in the matrix. The plurality of hetero-nanoparticles include an atom having an atomic weight larger than the atoms in the plurality of matrix nanoparticles.

In some aspects, embodiments disclosed herein relate to a thermoelectric converter that includes one or more first legs, each including an n-doped composite, and one or more second legs, each including a p-doped composite. The n-doped and p-doped composites include a matrix having a plurality of matrix nanoparticles and a plurality of hetero-nanoparticles dispersed in the matrix. The plurality of hetero-nanoparticles include an atom having an atomic weight larger than the atoms in the plurality of matrix nanoparticles. The plurality of matrix nanoparticles and plurality of hetero-nanoparticles in each of the n-doped and p-doped composites can be the same or different.

In some aspects, embodiments disclosed herein related to a method of making a composite for thermoelectric converter applications. The method includes providing a mixture a plurality of matrix nanoparticles and a plurality of hetero-nanoparticles and applying current activated pressure assisted densification to form the composite.

### BRIEF DESCRIPTION OF THE DRAWINGS

FIG. 1 shows temperature-dependent thermal conductivity of SiGe nanoparticle composites.

FIG. 2 shows how electrical conductivity, Seebeck coefficient, power factor, and thermal conductivity are all related to the concentration of free carriers.

FIG. 3 shows the most favorable carrier density for a high efficiency thermoelectric material. The narrow band corresponds to a Seebeck enhancement for quantum dots.

FIG. 4 shows a comparison of energy positions and density of states (DOS) concentrations for semiconductors of varying dimensionality.

FIG. 5 shows a thermoelectric converter having a single n-doped leg and a single p-doped leg. The legs are made from composites of the present invention.

FIG. 6 shows a cut away view of a thermoelectric converter platform having a plurality of legs which can be paired n- and p-doped composites of the invention.

FIG. 7 shows a thermoelectric converter in the form of a prototype unicouple assembly.

FIG. 8 shows the tradeoffs in thermoelectric generator design based on thermal resistance versus heat flow, temperature difference, and electrical power.

FIG. 9 shows the major processing steps used in large scale manufacture of high performance power generation devices.

FIG. 10 shows the tailoring of the surface structure of nanoparticles in the presence of a surfactant. The choice of surfactant can be used to alter the size of the nanoparticle and protects the nanoparticle prior to compaction.

FIG. 11 shows a three step nanoparticle sintering and fusion process which includes particle deposition, surfactant removal and consolidation; A is the top surface, B is a layer containing nanoparticles with surfactant, C is the bottom surface.

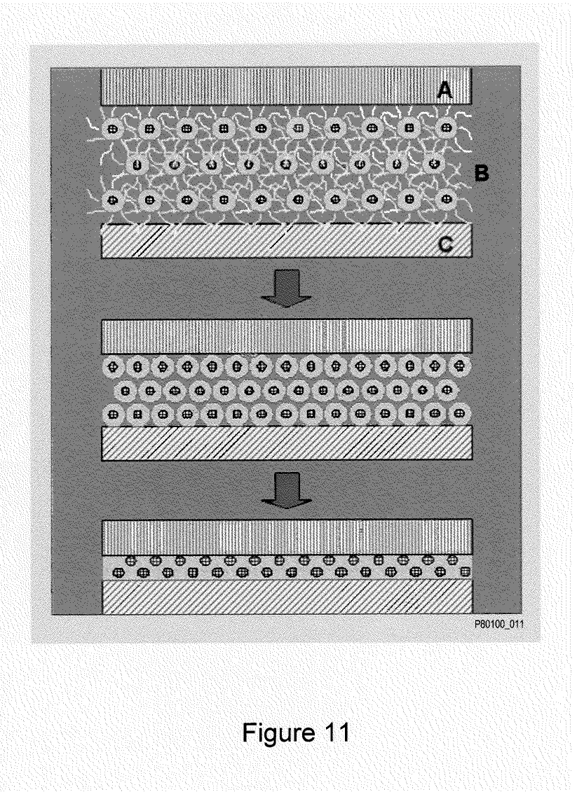

### DETAILED DESCRIPTION

The present invention is directed, in part, to thermoelectric composites. Composites of the invention employ both nanoparticle matrix materials as well as nanoparticle inclusions having at least one heavy atom component. The use of an all nanoparticle composite system with heavy atom inclusions allows the resultant composite to effectively scatter short, medium and long wave phonons resulting in a composite that minimizes thermal conductivity, while providing high electrical conductivity and thermopower as measured by the composite's thermoelectric figure of merit (ZT). Composites of the invention can have a ZT of at least 5 at elevated temperatures ranging as high as from about 600° C. to about 1000° C. In some aspects, composites of the invention have thermoelectric figures of merit ZT greater than 5. Without being bound by theory, the presence of low-dimensional nanoparticle structures can provide a steep reduction in thermal conductivity compared to a bulk materials, resulting in a theoretical 5-fold increase in ZT when mixing hetero-nanoparticles in a nanostructured matrix. Graded doping and particle size along the thermal gradient can provide further ZT and efficiency improvements.

In an exemplary embodiment, composites of the present invention can be based on a silicon-germanium nanoparticle alloy system, the nanostructure and mass difference between Si and Ge can be effective in short wave phonon scattering, while high mass hetero-nanoparticles can effectively scatter medium and long wave phonons. Selective doping particles in the matrix nanoparticles can increase carrier density and retain good mobility. The use of nanoparticles can maximize density of states near the Fermi level for increased thermoelectric power, as measured by a high Seebeck coefficient, as described further below.

By way of comparison, Se and Te based systems have been indicated to have the highest performance with ZT values exceeding 2. However, their low thermal stability limits their application to temperatures around 300° C. Se and Te are also toxic and their abundance is low making wide spread use, such as in the transportation sector or commercial electronics, not practical. Similarly, bismuth and tellurium are 1625 times and 13,000 times less abundant than Si, C and B. The latter are therefore available at much lower cost.

The present invention is also directed, in part, to a thermoelectric converter that uses composites of the invention in its component legs. The composites making up the legs can be manufactured as p-doped and n-doped composites. Such devices can exhibit about 5-fold improvements over current state-of-the-art 5% efficient devices based on Bi₂Te₃ composites. Such improvements are realized with high hot side temperatures and high differential between hot side and cold side temperatures (ΔT). For example, thermoelectric converters of the present invention can operate at a hot side temperature in a range from about 600° C. to about 900° C. with ΔT ranging from between about 500 to about 800° C.

In an exemplary embodiment, more efficient and higher temperature thermoelectric converter modules, such as those that can be used in automotive applications, can be developed based on hetero-nanoparticle-doped n-Si_{0.8}Ge_{0.2}/p-B₄C composites. The resulting modules can convert 20-30% of heat into electrical energy and, when fully implemented, can save as much as 150,000,000 gallons of gasoline per day and reduce CO₂ emissions by 1,300,000 t/day. The low cost, light weight, high temperature materials system based on n-type Si_{0.8}Ge_{0.2} and p-type B₄C, which exhibit high temperature stability beyond 1000° C., so that the nanostructure can be stable at temperatures close to 900° C. These materials can display high temperature stability observed in 10 nm thin film superlattice structures.

The present invention is also directed, in part, to thermoelectric composite manufacturing methods. Composites of the invention are constructed in a ground up approach employing a readily scalable preparation of the requisite nanoparticles through surfactant stabilized reduction of metal salts. The nanoparticle synthesis approach provides excellent size and size distribution control at low cost and is amenable to large scale mass production. In some aspects, the nanoparticle synthesis approach can be employed for simultaneous nanoparticle formation and doping of the matrix nanoparticles, which would otherwise be highly complex and difficult to fabricate by other methods.

By way of comparison, although ball milling techniques to produce nanoparticles have benefitted from improved equipment recently, contamination with milling material due to wear/loss of milling balls occurs frequently, especially with hard materials such as carbides, silicides and borides. It can be labor intensive to keep a ball milling system well maintained to prevent energy variations, which can lead to inconsistent results. Furthermore, such systems provide limited control over particle size and distribution, because at a certain size, the nanoparticles start to agglomerate and fuse again. Bottom-up solution synthesis avoids these issues providing excellent size and size distribution control via surfactant choice and concentration.

The surfactant stabilized nanoparticle components, both the matrix nanoparticles and the heavy atom-containing hetero-nanoparticles, can be compacted under mild conditions using spark plasma sintering (SPS). Such a process results in high composite density, while maintaining the integrity of the nanoparticle structure by minimizing grain growth during composite formation. The composite product maintains the “zero dimensional” characteristics provided by the nanoparticle components. In some aspects, the gentle compaction technique employed in methods of the invention provides near 100% dense composites while substantially preserving the nanoparticle size.

Again, by way of comparison, standard hot pressing techniques employ high temperatures and pressures over long periods of time to consolidate powders to densities above 90%. These extreme processing conditions lead to accelerated grain growth, providing larger than desired nanoparticles, which is detrimental to thermoelectric performance. Moreover, while the residual porosity obtained using standard hot press techniques provides a positive benefit of reducing thermal conductivity, the residual porosity also reduces electrical conductivity, which leads to a low power factor and low ZT and efficiency. Spark Plasma sintering (SPS) avoids these problems. It is a fast and gentle process minimizing grain growth and provides near 100% dense specimens.

From nanoparticle preparation through compaction, methods of the invention for making composites of the invention are more efficient, readily scalable and can be used to manufacture higher temperature thermoelectric converters than other methods employed in the art. Methods of the invention are also suitable for use in large scale applications and in large device manufacturing.

As used herein, the term “composite” refers to a material made by mixing two or more constituent materials with different physical and/or chemical properties. These properties can be enhanced and/or shared in the overall composite structure. A composite, as used herein has a first constituent that is the main bulk phase and makes up the majority of the composite and is referred to herein as the matrix. The matrix employed herein has a nanoparticle structure. The second component of composites of the invention is a heavy-atom containing hetero-nanoparticle and represents the minor component of the composite. In some embodiments, this second component is evenly dispersed in the matrix, while in other embodiments, this second component is present in a gradient concentration. Composite components of the invention have the shared property of phonon scattering and provide a material with low thermal conductivity. In particular, the composites of the invention having matrix nanoparticles and hetero-nanoparticles provide a full spectrum of low, medium, and high wave phonon scattering.

As used herein, the term “matrix” refers to the bulk material of a composite. Matrix materials of the present invention include matrix nanoparticles. Matrix nanoparticles can be n-doped or p-doped and make up the bulk phase in composites of the invention.

As used herein, the term “hetero-nanoparticle” or plural “hetero-nanoparticles,” or “h-NPs,” refers to the minor second component of composites of the invention. The hetero-nanoparticles of the invention include a heavy atom, such as a lanthanide, that has an atomic weight larger than the atoms present in the bulk matrix as well as transition metal compounds such as iron, manganese, chromium.

As used herein, the term “phonon” refers to a quasiparticle characterized by the quantization of the modes of lattice vibrations of periodic, elastic crystal structures of solids. Phonons play a role the physical properties of solids, including a material's thermal and electrical conductivities. A phonon is a quantum mechanical description of a type of vibrational motion in which a lattice uniformly oscillates at the same frequency.

As used herein, the term “thermoelectric figure of merit” or “ZT” is a dimensionless number that provides a measure of a material's effectiveness as a thermoelectric material. As described herein further below, a high ZT provides maximum thermoelectric performance and can be achieved by minimizing thermal conductivity and maximizing electrical conductivity and Seebeck coefficient. The ideal thermoelectric is a “phonon-glass electron-crystal” (PGEC) structure (amorphous glass=low thermal conductivity; crystal=high electrical conductivity). The best thermoelectric materials tend to be heavily doped semiconductors, because insulators have poor electrical conductivity and metals have low Seebeck coefficient.

As used herein, the term “doping particle” or “dopant” refers to the intentional impurities added during the manufacture of matrix nanoparticles of the invention to provide altered electrical properties to semiconducting matrix nanoparticles. Doping particles can include atoms that are deficient in electrons compared to the bulk matrix material, i.e. p-doping. Doping particles can include introduction of atoms that have a surplus of electrons compared to the bulk matrix material, i.e. n-doping. Lightly and moderately doped semiconductors are referred to as extrinsic. A semiconductor doped to such high levels that it acts more like a conductor than a semiconductor is referred to as degenerate. Matrix nanoparticles employed in the present invention are degenerate in some embodiments. With silicon as an exemplary semiconductor, a typical p-doping particle or p-dopant is boron, while a typical n-doping particle or n-dopant is phosphorus.

In some embodiments, the present invention provides a composite that includes a matrix having a plurality of matrix nanoparticles and a plurality of hetero-nanoparticles. The plurality of hetero-nanoparticles dispersed in the matrix include an atom having an atomic weight larger than the atoms in said plurality of matrix nanoparticles. The all-nanoparticle structure of the composite material provides effective scattering of short, medium, and long wave phonons leading to minimized and/or reduced thermal conductivity.

Thermoelectric performance is measured by the thermoelectric figure of merit ZT, which depends on the thermal conductivity, electrical conductivity and the Seebeck coefficient (the potential difference generated per degree of temperature difference between the hot and the cold side) according to equation (1):

$$ZT = \frac{σ \cdot {S}^{2}}{{κ}_{total}} \cdot T \qquad ( 1 )$$

φ=electrical conductivity
S²=thermopower (Seebeck Coeff)
T=temperature difference
K=total thermal conductivity
φS²=Power Factor

It has been indicated that it is possible to decouple the three parameters from each other by manipulating the thermoelectric material at the nanoscale. The thermal conductivity can be reduced by increasing the number of interfaces in a composite, because each interface scatters the thermal phonons impeding heat transfer, while largely retaining good electrical conductivity. A high Seebeck coefficient is achieved by maximizing the density of states near the Fermi level, which can be viewed as the ability to activate and move a large number of electrons resulting in a large potential difference between the hot and cold side. By contrast, ZT for most bulk materials tend to level out at approximately unity.

In a bulk semiconductor, there is a tradeoff between electrical conductivity (roughly linearly increasing with doping) and the Seebeck coefficient. As doping increases, the Fermi level moves towards the conduction (or valence) band and a more symmetrical carrier distribution around the Fermi level results, so that the thermal transport of electrons to the cold side is counteracted to a large extent by diffusion from the cold side of the thermoelectric back to the hot side. This is particularly high in metals, hence their low Seebeck coefficient. There are problems with degenerate (very high) doping levels including the reduction in carrier mobility due to the increased concentration of scattering centers caused by the dopants that provide the additional carriers.

The present invention addresses the aforementioned issues by producing composites with a high ZT through 1) Seebeck coefficient enhancement—maximize the asymmetry in the density of states (DOS) of the composite; 2) thermal conductivity reduction—minimize thermal conductivity by introducing phonon scattering for short (through Si—Ge alloy nanoparticles), mid- and long-wavelength phonons (through heavy atom-containing hetero-nanoparticles); and 3) electrical conductivity increases through use of high doping while maintaining high mobility.

In semiconductors, the thermal conductivity has contributions from both electrons (kₑ) and phonons (kₚ), with the majority usually coming from phonons (short/mid/long wavelength). In order to effectively reduce thermal conductivity, one needs to create a material that can scatter all three types. In some embodiments, composites of the present invention scatter short, medium and long wavelength phonons. The short wavelength phonon thermal conductivity can be reduced through alloying, for example. Thus, in some embodiments, composites of the invention employ an alloyed matrix nanoparticles.

Without being bound by theory, the atomic substitution and mass difference between the two constituents in an alloy causes the scattering of primarily short wavelength phonons and reduces lattice thermal conductivity. In some embodiments, thermal conductivity can be further lowered by introducing high atomic weight hetero-nanoparticles, which include an atom having an atomic weight larger than the atoms of the matrix nanoparticles. Such high mass atoms, include, for example, the lanthanides, although any atom having a higher atomic number/mass can be employed. The confluence of scattering short, mid, and long-wavelength phonons can provide an increase in room temperature ZT to about 2 due to a reduction in thermal conductivity while the thermoelectric power factor, can in some embodiments, remain relatively unchanged.

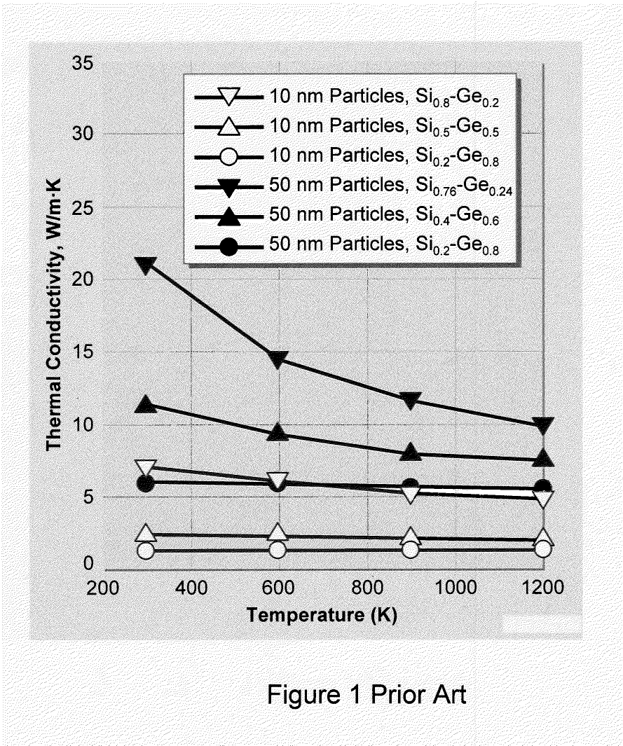

In addition to alloying and introducing heavy-atom doping, composites of the present invention also provide these components as nanoparticle structures. Nanostructured materials can further aid in scattering phonons resulting in reduced thermal conductivity. In particular, it has been indicated that in superlattices ZT increases were attributable to the reduction in thermal conductivity via scattering of short wavelength phonons. However, superlattices have to be grown by molecular beam epitaxy (MBE) or magnetron sputtering which is not amenable to large scale low cost manufacturing. It has been indicated that nanostructured bulk materials can provide lower thermal conductivities. For example, a 40% ZT increase from 1 to 1.4 has been demonstrated using a bulk material consisting of 100 nm size grains. It has also been demonstrated that particle size in a SiGe alloy composition affects thermal conductivity, as shown in FIG. 1. Thus, composites of the present invention can include both a nanostructured matrix and nanostructured hetero-nanoparticles with a grain size below about 50 nm. In some embodiments, matrix nanoparticles and hetero-nanoparticles can range in size from between about 5 nm to about 50 nm, including any values in between. In some embodiments, matrix nanoparticles and hetero-nanoparticles can range in size from between about 5 nm to about 30 nm. In some embodiments, matrix nanoparticles and hetero-nanoparticles can range in size from between about 5 nm to about 20 nm. Such nanostructured materials can aid in short wavelength phonon scattering.

In some embodiments, composites of the present invention can include a plurality of matrix nanoparticles, in particular, that range in size from between about 5 nm to about 50 nm. In some embodiments, matrix nanoparticles can range in size from between about 5 nm to about 35 nm. In some embodiments, the matrix nanoparticles can be sized around 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, up to about 35 nm, including fractions thereof.

In some embodiments, composites of the present invention can include a plurality of hetero-nanoparticles that range in size from between about 10 nm to about 60 nm, or from between about 10 nm to about 40 nm in other embodiments. In some embodiments, the heteronanoparticles can be sized around 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, up to about 60 nm, including fractions thereof. In some embodiments the hetero-nanoparticles are sized larger than the matrix nanoparticles. In some embodiments, the hetero-nanoparticles are sized comparable to the matrix nanoparticles.

The aforementioned nanoparticle sizing is achievable with the synthesis approach described herein further below, which has produced particle sizes below 30 nm, and below 10 nm, as a matter of routine. In some embodiments, the thermal conductivity reduction based on nanoparticle size alone can provide ZT values between about 2 to 3, in some embodiments, and ZT values greater than 5, some embodiments.

In some embodiments, additional improvement in ZT values are achieved by use of hetero-nanoparticles that have an atom of higher atomic mass than the matrix atoms. In some such embodiments, the hetero-nanoparticles can include a heavy metal or lanthanide atom. The presence of the hetero-nanoparticle can aid in mid- and long-wavelength phonon scattering.

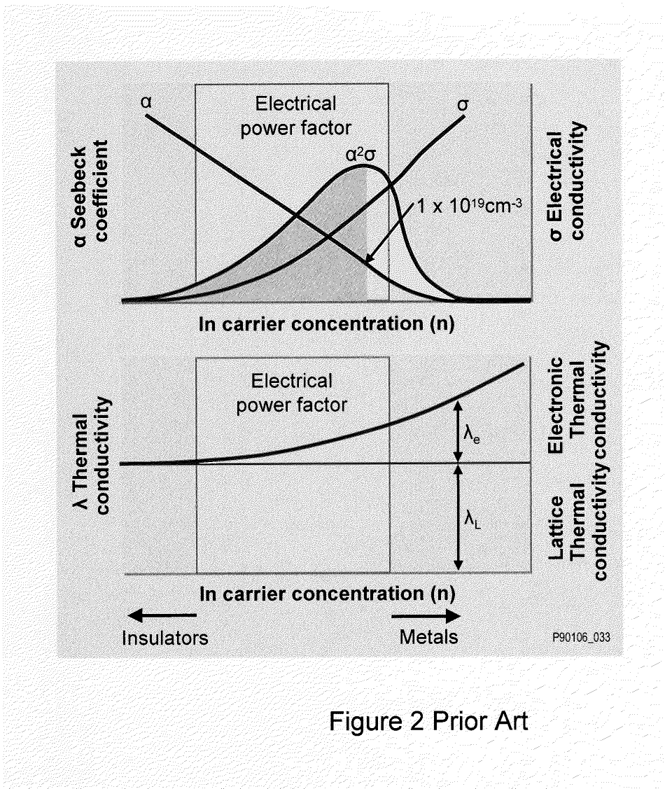

Additional performance enhancement can be achieved by increasing the thermopower of a thermoelectric material. Normally, the Seebeck coefficient and electrical conductivity are inversely correlated to each other such that the increase of one leads to the decrease of the other, as shown in FIG. 2. However, it has been indicated that it is possible to partially decouple the two parameters by appropriately nanostructuring the thermoelectric material.

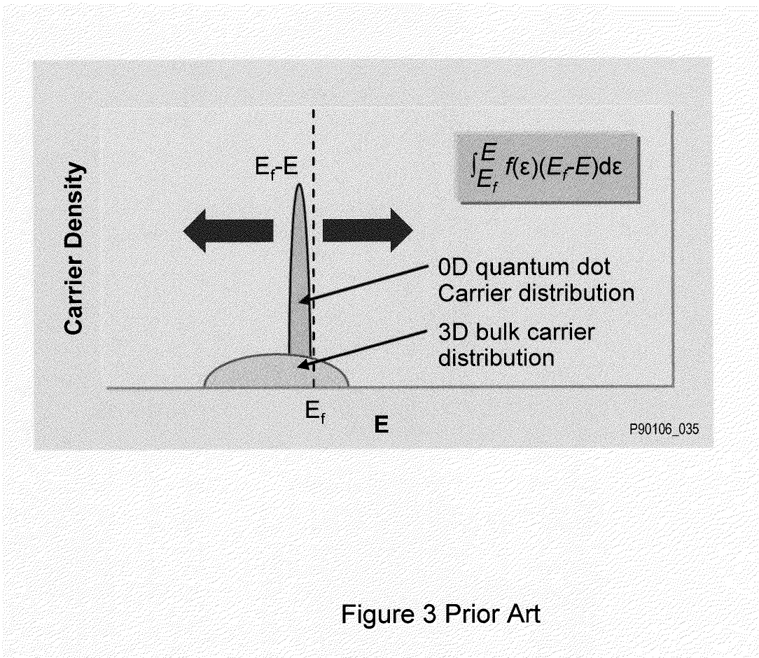

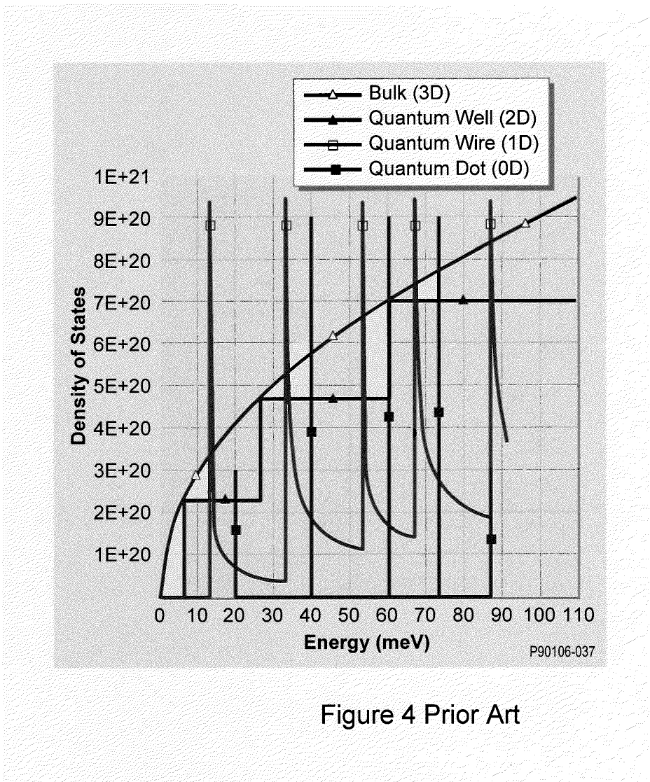

The Seebeck coefficient arises due to differential charge transport around the Fermi energy. Differential transport means that hot electrons/holes are transported to the cold side of the thermoelectric (conduction current) without the opportunity to return (minimized diffusion current). One driver for a high Seebeck coefficient is the asymmetry of the density of states (DOS) above and below the Fermi level, as indicated in FIGS. 3 and 4. Metals have a large carrier density near the Fermi level due to the partially filled conduction band. Thus, there is insufficient asymmetry to allow the electrons to freely move in all directions, hence the low Seebeck coefficient, but good electrical conductivity. Increasing electron confinement leads to an increasingly sharp DOS, which allows the engineering of significant asymmetry near the Fermi level. Nanoparticles approximate zero dimensional structures (quantum dots). This means that their density of states is nominally a Dirac delta function (very concentrated around a single point as indicated by the sharp black lines in FIG. 4. The degree of confinement and the energy level of this spike in density of states is a function of the size of the nanoparticle.

In the ideal case, only the hot electrons (higher energy, on the hot side) will conduct to the cold side and cannot diffuse to the hot side because of the lack of DOS at lower energy i.e. below the Fermi level. The closer the actual imbalance is to this ideal state, the larger the Seebeck coefficient will be. Superlattices show thermopower typically around 300-400 μV/K. With good hot electron filtering values in excess of 1000 μV/K, a ZT greater than 5 can be achieved. It has been indicated that the planar barriers in superlattices are far from being ideal for effective electron filtering due to laterally conserved momentum. Non-planar barriers can improve the DOS significantly.

A non-planar barrier is provided by the present invention as provided by the nanostructured bulk material by virtue of the small grains present as nanoparticles. This can place substantially all available DOS just above the Fermi energy assuring a high Seebeck coefficient as long as there are some available carriers to transport heat from hot to cold. In order to provide mobile carriers in this structure, composites of the invention can have a sufficient amount of highly doped hetero-nanoparticles. These dopant particles release mobile carriers into the undoped matrix. The doping concentration can be in the range from between about 10¹⁹ to about 10²⁵ and higher and can readily be higher if desired. One skilled in the art will recognize than an upper limit may be set based only on the solubility of the dopant in the base semiconductor material.

In view of the combined effects of nanoparticle structuring of the entire composite, the presence of heavy atoms in the hetero-nanoparticles, and alterations in the density of states of the matrix, composites of the present invention can display a thermoelectric figure of merit (ZT) in a range between about 1 to about 5, including 1, 2, 3, 4, and 5, including fractions thereof. In some embodiments, composites of the invention have a ZT in a range from between about 2 to about 5, including 2, 3, 4, and 5, including fractions thereof. In some embodiments, composites of the invention have a ZT of at least about 5. In some embodiments, composites of the invention have a ZT of at least about 5 and up to about 10.

In some embodiments, composites of the invention can have the plurality of hetero-nanoparticles dispersed uniformly throughout the matrix. Uniform dispersion throughout the matrix nanoparticles can be achieved with ease and allows for rapid manufacture. In other embodiments, composites of the present invention can have the plurality of hetero-nanoparticles dispersed in a gradient concentration in the matrix. In some such embodiments, the gradient can be configured to increase doping in the direction of the cold side. Such gradient concentrations of the hetero-nanoparticles can provide increases to ZT. Similarly, in some embodiments, any n- or p-dopant material in the matrix nanoparticles can also be present in a gradient concentration. Gradient hetero-nanoparticles and dopants are readily prepare by methods known in the art of solid composite manufacture and include, for example, simple gradient mixing of the materials prior to exposure to the compaction method described herein further below. In some embodiments, the hetero-nanoparticles can be present in a concentration ranging from between about 0.1% to about 10.0% w/w, including any amount in between and fractions thereof.

In some embodiments, composites of the invention employ matrix nanoparticles that are n-doped or p-doped semiconductors. Exemplary semiconductors include, without limitation, silicon, germanium, alloys of silicon and germanium, ternary adamantine semiconductors (ternary pnictides) of the II-IV-V2 type such as but not limited to CaCN₂, ZnGeN₂, MgSiP₂, ZnSiP₂, ZnSnP₂, ZnSiAs₂, CdSiP₂, boron carbides, carbon, silicon carbide, aluminum antimonide, aluminum arsenide, aluminum nitride, aluminum phosphide, boron nitride, boron phosphide, boron arsenide, gallium antimonide, gallium nitride, gallium phosphide, gallium arsenide, indium antimonide, indium phosphide, indium arsenide, indium nitride, aluminum gallium arsenide, indium gallium arsenide, indium gallium phosphide, aluminum indium arsenide, aluminum indium antimonide, gallium arsenide nitride, gallium arsenide phosphide, gallium arsenide antimonide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, indium gallium arsenide antimonide, indium phosphide arsenide antimonide, aluminum indium arsenide phosphide, aluminum gallium arsenide nitride, indium gallium arsenide nitride, indium aluminium arsenide nitride, gallium arsenide antimonide nitride, gallium indium nitride arsenide antimonide, gallium indium arsenide antimonide phosphide, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, cuprous chloride, copper sulfide, lead selenide, lead(II) sulfide, lead telluride, tin sulfide, tin sulfide, tin telluride, lead tin telluride, thallium tin telluride, thallium germanium telluride, bismuth telluride, cadmium phosphide, cadmium arsenide, cadmium antimonide, zinc phosphide, zinc arsenide, zinc antimonide, titanium dioxide, anatase, titanium dioxide, rutile, titanium dioxide, brookite, copper(I) oxide, copper(II) oxide, uranium dioxide, uranium trioxide, bismuth trioxide, tin dioxide, barium titanate, strontium titanate, lithium niobate, lanthanum copper oxide, lead(II) iodide, molybdenum disulfide, gallium selenide, tin sulfide, bismuth sulfide, gallium manganese arsenide, indium manganese arsenide, cadmium manganese telluride, lead manganese telluride, lanthanum calcium manganate, iron(II) oxide, nickel(II) oxide, europium(II) oxide, europium(II) sulfide, chromium(III) bromide, copper indium gallium selenide, copper zinc tin sulfide, copper indium selenide, silver gallium sulfide, zinc silicon phosphide, arsenic selenide, platinum silicide, bismuth(III) iodide, mercury(II) iodide, thallium(I) bromide, selenium, and iron disulfide, and mixtures of any of the aforementioned semiconductors.

In some embodiments, matrix nanoparticle semiconductors are chosen that have atoms selected only from periods 1 through 4 of the periodic table. As will be evident to the skilled artisan, the atoms of the hetero-nanoparticles advantageously can have a substantially higher atomic mass than the atoms of the matrix nanoparticles to maximize short, medium and long wavelength phonon scattering. Thus, while a semiconductor based on europium, for example, is functional in the composites of the invention, the advantage of the disparate atomic mass with the hetero-nanoparticle may be reduced.

In some embodiments, composites of the invention employ matrix nanoparticles that include silicon and germanium, especially silicon germanium nanoparticle alloys. In some such embodiments, the matrix nanoparticles can have the composition Si_{0.8}Ge_{0.2}, although the alloy can include compositions based on primarily germanium, such as Si_{0.2}Ge_{0.8}. One skilled in the art will recognize the ability to use any ratio of these two elements, including from between about 0.8:0.2 to about 0.2:0.8, including any ratio value in between. Germanium differs from silicon in that the supply for germanium is currently limited by the availability of exploitable sources, while the supply of silicon is only limited by production capacity since silicon comes from ordinary sand or quartz. As a result, silicon is currently obtained at a substantially lower cost than germanium. Thus, the choice of exact ratio can take into account these cost differences, if so desired. In some embodiments, a silicon-germanium alloy can have a nanoparticle size in the composite of about 10 nm after compaction. This can be based on a nanoparticle size prior to compaction less than 10 nm, for example.

In some embodiments, composites of the invention can further include n-type doping particles. When employing silicon-germanium alloys, such n-type doping particles are selected from the group consisting of phosphorus, antimony, bismuth, silicon fluoride, silicon oxide, germanium fluoride, and germanium oxide. In some embodiments, the n-doping agent is phosphorus. In some embodiments, when employing silicon-germanium alloys, the composite of can include p-type doping particles such as boron. Other p-dopants include Al, Ga, In, Mg, Ca, Sr, Ba, Fe, Mn, and Zn.

In some embodiments, the composite of the invention employing a silicon-germanium nanoparticle alloy can include a plurality of hetero-nanoparticles which include silicides or germanides. In some such embodiments, the silicides and germanides are selected from the group consisting of tungsten silicide, cerium silicide, iron silicide, manganese silicide, chromium silicide, tungsten germanide, cerium germanide, iron germanide, manganese germanide, chromium germanide, and combinations thereof. One skilled in the art will recognize that any heavy atom silicide or germanide can be employed, including lighter atoms than those exemplified, with the proviso that the heavy atom of choice has an atomic mass greater than germanium, the heavier component of the alloy. Although heavier atoms can generally perform better than lighter ones, one skilled in the art will recognize that many lighter atoms can provide economic advantages, especially over considerably expensive heavy rare earth elements. The exact choice of heavy atom can be selected to balance performance versus cost. Thus, any stable d-block transition metal silicide or germanide or any stable f-block lanthanide/actinide silicide or germanide can be included in the hetero-nanoparticle. Any of the aforementioned silicide or germanide compounds can be used in combination. In some embodiments, combination silicide/germanides can include, for example, tungsten silicide with cerium silicide, tungsten silicide with tungstem germanide, tungsten silicide with cerium germanide, cerium silicide with tungsten germanide, cerium silicide with cerium germanide, and tungsten germanide with cerium germanide. Combinations of three component silicide/germanide hetero-nanoparticles can also be employed, as well as four component hetero-nanoparticles, as will be evident to the skilled artisan.

In some embodiments, composites of the invention can include matrix nanoparticles that include boron and carbon. Some such matrix nanoparticles can include B₃C, B₄C, B₅C or combinations thereof. One skilled in the art will recognize that the doping of a boron/carbon based composite can be altered by increasing or decreasing the amount of carbon present. In some embodiments, the base matrix nanoparticles are B₄C and the doping can include appropriate amounts of B₃C or B₅C. In some embodiments, when boron/carbon based composite structures are employed, hetero-nanoparticles can be selected from the group consisting of silicon carbide, tungsten carbide, silicon boride, tungsten boride, and combinations thereof. In some embodiments, other carbides and borides can be used with the proviso that the hetero-nanoparticle include an atom having an atomic mass greater than carbon, the heavier element of the base matrix composite. Other carbides can include, for example, scandium carbide, yttrium carbide, aluminum carbide, lanthanum carbide, among other d-block and f-block carbides. Borides can similarly be based on other d-block or f-block transition metals, including for example, yttrium, lanthanum, osmium, rhenium, vanadium, chromium, and iron. Any of the aforementioned carbide and boride compound can be used in any combination. For example, combinations include, without limitation, silicon carbide and tungsten carbide, silicon carbide and silicon boride, silicon carbide and tungsten boride, tungsten carbide and silicon boride, tungsten carbide and tungsten boride, and silicon boride and tungsten boride. Combinations of three component boride/carbide hetero-nanoparticles can also be employed, as well as four component boride/carbide hetero-nanoparticles, as will be evident to the skilled artisan.

In some embodiments, composites of the invention can include matrix nanoparticles that include silicon and carbon. Some such matrix nanoparticles can include SiC, Si₂C, SiC₃ or combinations thereof. In some embodiments, when silicon/carbon based composite structures are employed, hetero-nanoparticles can be selected from the group consisting of tungsten carbide, iron carbide, manganese carbide, chromium carbide, the respective silicides, and combinations thereof. In some embodiments, other carbides and borides can be used with the proviso that the hetero-nanoparticle includes an atom having an atomic mass greater than carbon, the heavier element of the base matrix composite. Other carbides can include, for example, scandium carbide, yttrium carbide, aluminum carbide, lanthanum carbide, among other d-block and f-block carbides. Borides can similarly be based on other d-block or f-block transition metals, including for example, yttrium, lanthanum, osmium, rhenium, vanadium, chromium, and iron. Any of the aforementioned carbide and boride compound can be used in any combination. For example, combinations include, without limitation, iron carbide and tungsten carbide, iron carbide and cerium boride, lanthanum carbide and tungsten boride, tungsten carbide and iron boride, tungsten carbide and tungsten boride, and chromium boride and tungsten boride. Combinations of three component boride/carbide hetero-nanoparticles can also be employed, as well as four component boride/carbide hetero-nanoparticles, as will be evident to the skilled artisan.

In some embodiments, the present invention provides a thermoelectric converter that includes one or more first legs, each including an n-doped composite, the n-doped composite including a first matrix that includes a first plurality of matrix nanoparticles and a first plurality of hetero-nanoparticles. The first plurality of hetero-nanoparticles is dispersed in the first matrix, and the first plurality of hetero-nanoparticles include an atom having an atomic weight larger than the atoms in the first plurality of matrix nanoparticles. The thermoelectric converter also includes one or more second legs, each including a p-doped composite, the p-doped composite including a second matrix that includes a second plurality of matrix nanoparticles and a second plurality of hetero-nanoparticles. The second plurality of hetero-nanoparticles is dispersed in the second matrix, and the second plurality of hetero-nanoparticles includes an atom having an atomic weight larger than the atoms in the second plurality of matrix nanoparticles.

In some embodiments, the thermoelectric converter of the invention employs n-doped and p-doped composite legs that are capable of scattering short, medium, and long wave phonons, as described herein above. Thus, the thermoelectric converters of the invention can have n-doped and p-doped composites that individually have a thermoelectric figure of merit (ZT) in a range between about 1 to about 5, including 1, 2, 3, 4, and 5, and any fraction thereof. In some such embodiments, the thermoelectric converter of the invention can employ n-doped and p-doped composite legs that have a ZT in a range from between about 2 to about 5, including 2, 3, 4, and 5, and any fraction thereof. In still further embodiments, the thermoelectric converters of the invention have n-doped and p-doped composite legs that have a ZT of at least 5 and up to about 10. In some embodiments, the thermoelectric converter of the invention operate at an efficiency in a range from between about 20% to about 30%, when employing composites of the invention described herein above. In some embodiments, thermoelectric converters can operate at higher efficiencies, such as 35%, 40%, 50% and higher, including any value in between, and fractions thereof.

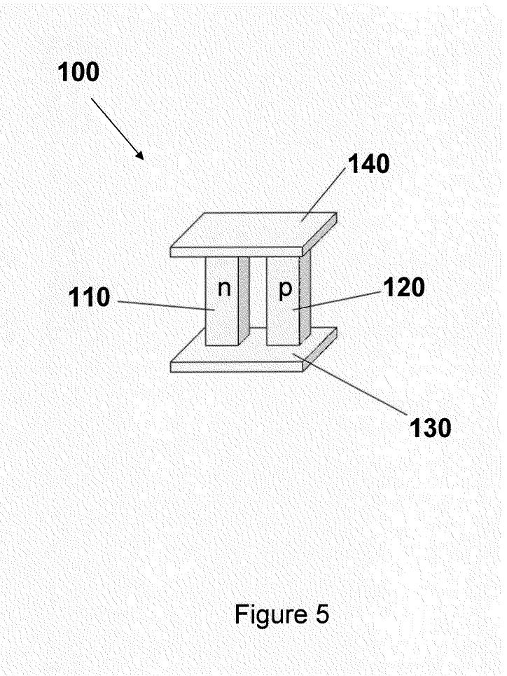

Referring now to FIG. 5, there is shown a thermoelectric converter 100 of the present invention having a single n-doped composite leg 110 and a single p-doped composite leg 120. While, FIG. 5 shows one p-n leg pair, 110 and 120, any number of p-n leg pairs may be present in a thermoelectric converter of the invention. P-n leg pair 110 and 120 can have a height ranging from between about 0.5 cm to about 5 cm, including about 0.5, 1.0, 1.5, 2.0, 2.5, 3.0, 3.5, 4.0, 4.5, and 5.0 cm including any value in between and fractions thereof. P-n leg pair 110 and 120 can be separated by an insulating layer (not shown). The distance separating the p-n leg pair 110 and 120 can be in a range from between about 500 microns to about 5000 microns. It has been indicated in lower temperature applications, thin film devices with thicknesses ranging from between about 500 to 5000 microns provide useful performance, although it is understood that there is a strong dependence on the specific temperature conditions and temperature differential.

Thermoelectric converter 100 can include a platform 130 on which one or more first legs and one or more second legs are disposed, with a provision for electrically insulating the one or more first legs from the one or more second legs. Thermoelectric converter 100 can further include a plate 140 equipped with electrical contacts, which can be operably-linked to the one or more first legs and the one or more second legs, with plate 140 being distal to platform 130. Plate 140 can be in contact with the hot side of the thermoelectric converter while platform 130 is on the cold side. Plate 140 can be in the form of a thin film. For example, plate 140 can include a film of approximately 100 microns. Plate 140 can have a range of thickness from between about 500 microns to about 5000 microns. Using legs that include composites of the invention described herein above, the thermoelectric converters of the invention are capable of operating at an upper temperature limit ranging from between about 600° C. to about 900° C.

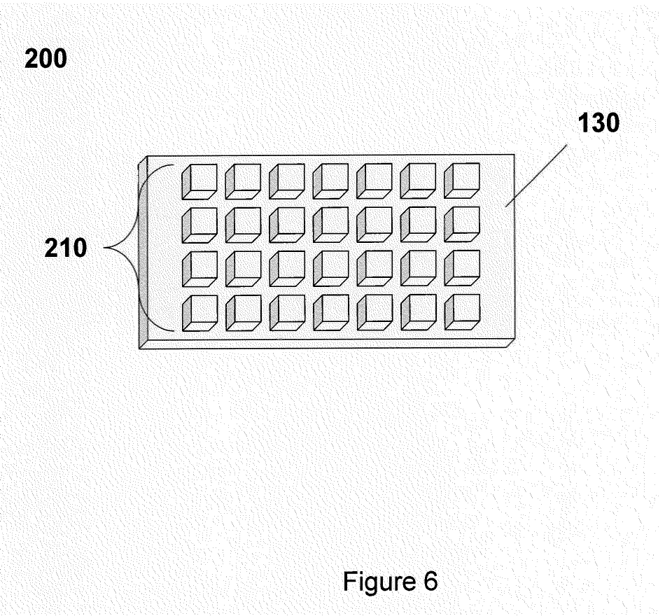

Referring now to FIG. 6, there is shown view of a thermoelectric converter 200 of the invention having p-n leg pairs 210 disposed on platform 130, with plate 140 not shown for clarity. The p and n composite legs can be organized in any orientation on this array, with appropriate insulation between the legs. Thus, in some embodiments, p-n leg pairs 210 can be oriented parallel to the short side, and in other embodiments p-n leg pairs 210 can be oriented parallel to the long side. One skilled in the art will recognize that this array need not be rectangular and other array configurations can be designed, such as square arrays. The number of p-n leg pairs 210 can be in a range from about 2 pairs of legs up to about 500 pairs of legs or more.

With reference to both FIGS. 5 and 6, the n- and p-doped composite legs can be made of the same matrix material, in some embodiments. For example, the matrix nanoparticles for the n- and p-doped composite legs can both be based on SiGe alloy. In some such embodiments, the composite structure can include matrix nanoparticles having the composition Si_{0.8}Ge_{0.2}, although the alloy can include compositions based on primarily germanium, such as Si_{0.2}Ge_{0.8}. One skilled in the art will recognize the ability to use any ratio of these two elements, including from between about 0.8:0.2 to about 0.2:0.8, including any ratio value in between. Such composites can utilize the same hetero-nanoparticles and dopants, as described herein above. In some embodiments, where the same matrix material is used for the n- and p-doped composite legs, the matrix can be based on boron and carbon, and in specific embodiments based on B₄C, as described above. Also with reference to both FIGS. 5 and 6, the n- and p-doped composite legs can be made of different matrix materials, in some embodiments. In some such embodiments, the n-doped composite leg is based on the silicon germanium alloys described above and the p-doped composite leg is based on the boron carbide B₄C structure.

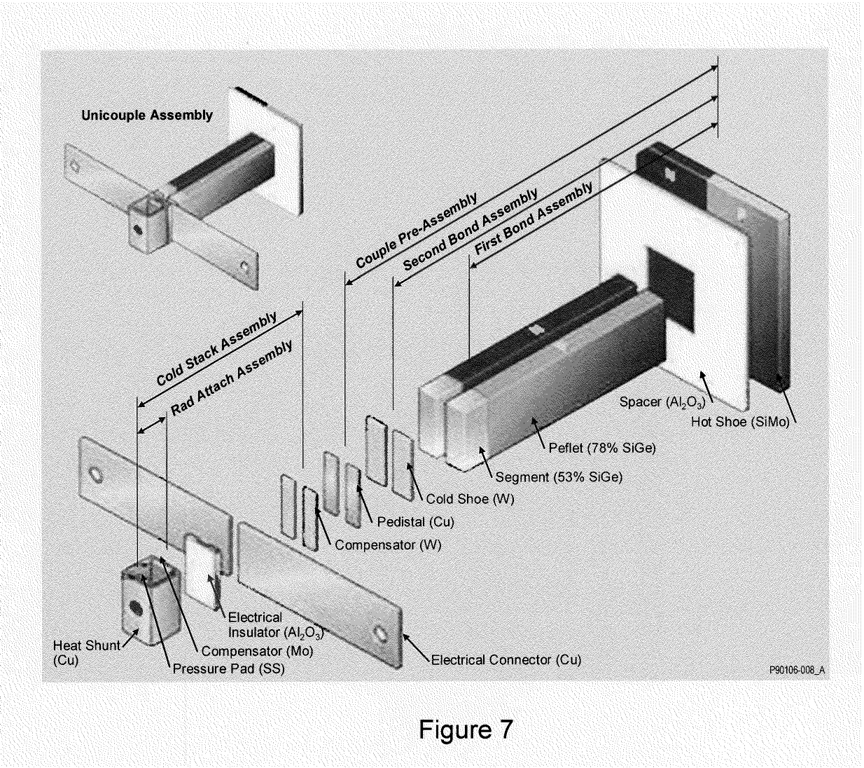

In some embodiments, a thermoelectric converter of the present invention can take the form of a unicouple assembly. Such a unicouple assembly is shown in FIG. 7 and includes a hot shoe, p- and n-doped composite legs, and a cold stack assembly. In this design the unicouple is cantilevered from a radiator using a heat shunt. In some embodiments, compositionally graded inter layers can be added to mitigate mismatches in the coefficient of thermal expansion (CTE). Couple manufacturing involves making progressively lower temperature bonds that follow the temperature gradient developed across the leg length. The Si_{0.8}Ge_{0.2}/B₄C synthesis and leg consolidation methods described herein can produce components that can be directly inserted into this fabrication sequence. The cold shoe can connect to an external radiator using stainless steel bolts or any other attachment means apparent to the skilled artisan. A substantial temperature gradient can be developed across the legs using this design.

In some embodiments, a nanostructured thermal/electrical interface material can be employed that can have graded porosity to accommodate thermal expansion mismatches and stresses during operation between the thermal top plate and the thermoelectric material and to provide improved electrical contact. Depending on the hot side operating temperature and the CTE of the adjacent materials systems, a suitably formulated copper-nickel alloy for corrosion protection with other additives to tailor the CTE can be used.

Thermal modeling can be employed to estimate system mass for each thermoelectric p-n pair. From this model and the thermal properties of couple leg materials, leg length can be optimized with a view toward any particular system requirements. Insulation can also be varied to accommodate changes in leg length.

Hot shoes directly bonded to thermoelectric legs offer the lowest weight for unicouple construction. In some embodiments, however, hot shoes, bonding material, leg composition, or any combination of the three can be selected to minimize any differences in coefficient of thermal expansion. In some embodiments, the leg properties can be assessed and altered using a mechanical preload method using an isotropic refractory metal hot shoe with machined shallow wells that will accept the legs. In some embodiments, this can be accomplished by inserting nickel foil in the wells, which increases contact area and provides compliance at hot shoe surfaces. The preload can be applied to the legs at the cold side using electrically isolated springs and a retention mechanism.

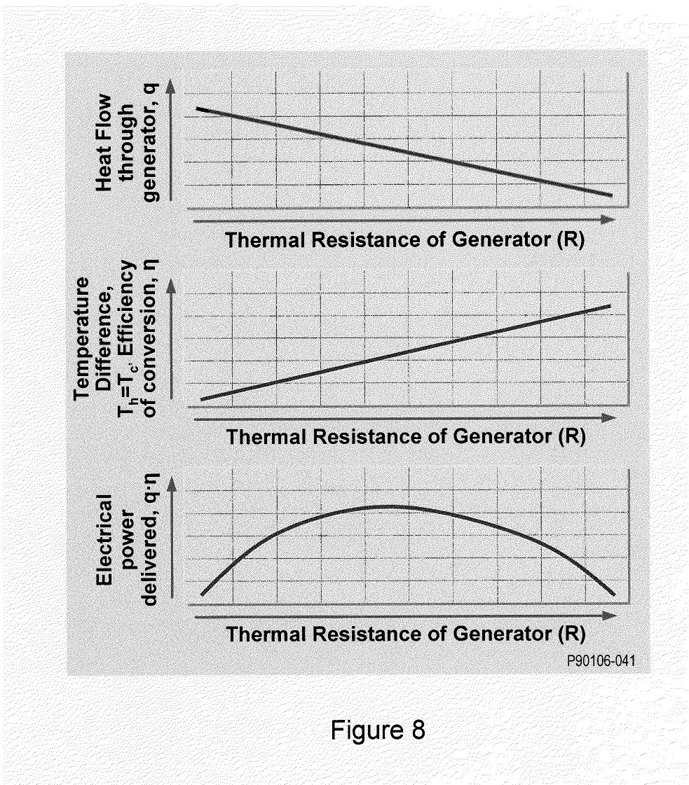

In some embodiments, a thermoelectric converter of the present invention takes the form of a thermoelectric generator. A thermoelectric generator for a vehicle, for example, can include geometric scale optimization with respect to the input and output thermal resistances from the two interfaces one to the heat source, such as an exhaust pipe, and the other to a cooling system. FIG. 8 illustrates the tradeoffs that can be considered in design. The top plot shows that the lower the thermal resistance (i.e., the shorter and more tightly space that thermoelectric elements are), the more heat will flow through the generator which then may be turned into useful electrical power. However, the middle plot shows that the lower the thermal resistance, the smaller the temperature difference (Tₕ-T_{c}) and by extension the lower the thermodynamic efficiency. The end user values the electrical power delivered (q.η) which is optimized at a point of moderate heat flow and moderate temperature difference (lower plot).

A number of high ZT superlattice materials have been developed, but they are so thin that the thermal resistance (R) is too low resulting in poor performance. At the other end of the spectrum are commercial thermoelectric devices that are too thick to deliver optimal power in many applications (R too high). In some embodiments thermoelectric devices of the present invention have a thickness ranging from between about 100 microns to about 5000 microns which can deliver optimal thermal resistance for a wide range of applications. Thus, thermoelectric converters of the present invention employ high ZT nanomaterials with a device geometry scaled to deliver optimal output power.

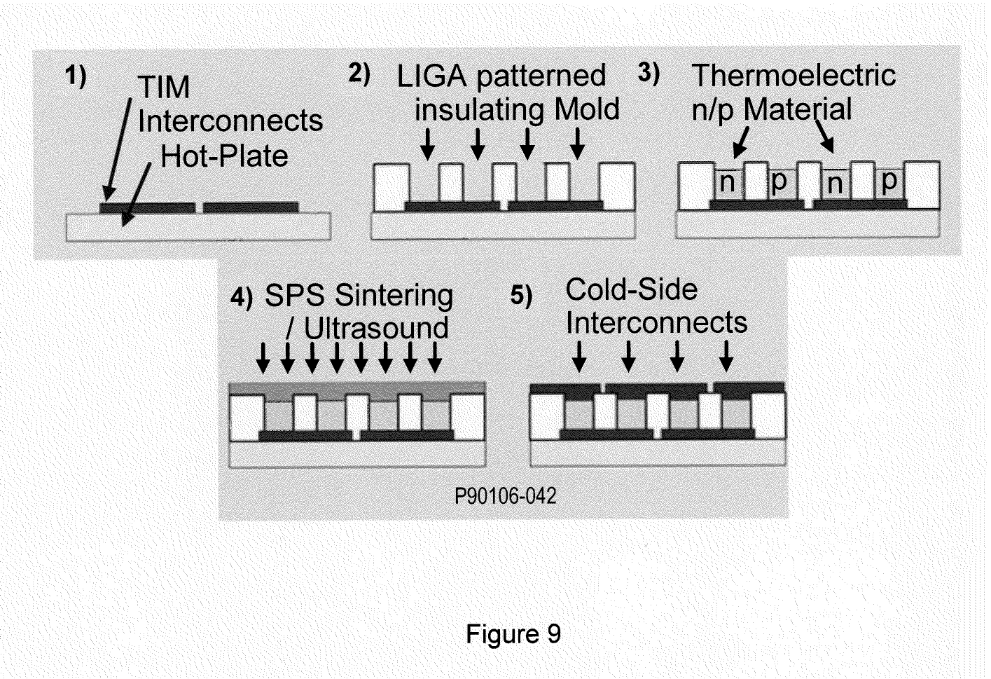

An efficient low cost thermoelectric device manufacturing process is shown in FIG. 9. In case of a high temperature device, the manufacturing progresses from the hot component side to the cold component side to eliminate excessive thermal stresses for highest device stability and robustness. The process includes (1) hot side metal interconnect formation using lithography and placed on one side the desired insulating material separating the n- and p-legs or the insulator is bonded to a solid hot plate such as molybdenum. This insulating material can be a porous alumina or zirconia material that exhibits the proper thermal stability at the targeted operating temperature and at the predetermined thickness for the thermoelectric elements. This material is then etched using LIGA or Lithography, Electroforming, and molding to produce a mold (2), followed by (3) deposition of the thermoelectric material (powder) across the entire wafer with the n- and p-type elements deposited in separate steps using impeller dry blending (IDB) to create a functionally graded material (FGM). The thermoelectric elements are then densified (4) using spark plasma sintering with moderate pressure or ultrasound and the device structure completed by forming the upper metal interconnects (5). These can be made, for example, using nanocopper, which can be generated by reduction of copper salts in the presence of bidentate amine ligands, in the presence of a mono-alkylamine, the surfactant mixture stabilizing copper nanoparticles. It can be formed as a graded material with varying porosity forming a thermal interface material with high ductility to accommodate thermal stresses without cracking. A final sintering step can be added to improve the electrical contact between the thermoelectric material and the contact material.

In some embodiments, the present invention provides a method of making a composite for thermoelectric converter applications that includes providing a mixture a plurality of matrix nanoparticles and a plurality of hetero-nanoparticles and applying spark plasma sintering (SPS) densification to form the composite. Composite manufacture is a bottom up approach which can accommodate de novo tailored nanoparticle preparation.

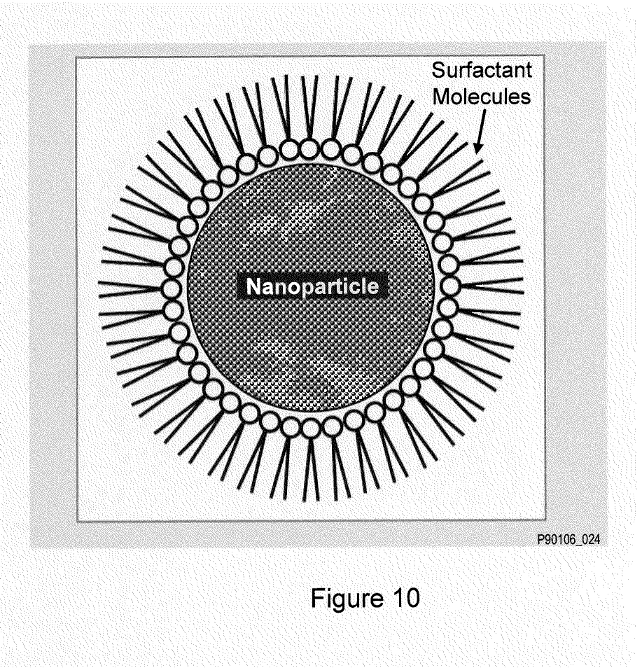

Non-stoichiometric compounds such as Si_{0.8}Ge_{0.2} and B₄C are difficult to produce as nanoparticles. The present invention solves this synthesis challenge by a versatile one-pot chemical approach that reduces appropriate metal halide precursors such as SiCl₄, GeCl₄, BCl₃, C₂Cl₄ to obtain the requisite nanoparticles with the desired composition. Suitable reducing agents include, for example, sodium borohydride and alkaline metals (Li/Na/K) with a promoter for atomic dispersion (small chunks, even Na-sand does not work) are used to ensure uniform reaction rate. Suitable surfactant mixtures are employed to bond to the nanoparticle particle surface, as indicated in FIG. 10, and control particle size as well as protecting the nanoparticle against oxidation. The surfactants can be chosen to be removable by choice of relative volatility and can be removed during the subsequent compaction process to protect the nanoparticles throughout the composite production process. The nanoparticles with their hydrophobic surfactant shell precipitate and can be readily isolated by centrifugation.

This approach allows the precise control over composition via the amount of precursors used in the reactions. The choice and concentration of surfactants are chosen for their ability to attach to the surface of the nascent nanoparticles inhibiting further growth once the surface of the nanoparticle is completely covered. This allows control over particle size and size distribution. For example, it is possible to produce mono-disperse silver and gold nanoparticles in the 1-2 nm size range. In general, stronger bonding surfactants and higher concentrations lead to smaller particles, narrower size distribution and high dispersion. This solution chemistry approach lends itself readily to significant scale-up compatible with standard large scale batch processing common in the chemical industry.

An exemplary n-type material preparation involves the fabrication of highly doped and undoped SiGe nanoparticles as well as hetero-nanoparticles with a higher mass. The synthesis of undoped SiGe can be carried out using reduction of suitable precursors such as SiCl₄ and GeCl₄. In some embodiments, this can be carried out separately with sodium borohydride (cheaper, easier to handle) to minimize complexity. The reduction chemistry is shown below:

SiCl₄+4NaBH₄4→nano-Si+4NaCl+2H₂+2B₂H₆ 1)

GeCl₄+4NaBH₄4→nano-Ge+4NaCl+2H₂+2B₂H₆ 2)

The nanoparticles thus obtained can be analyzed with respect to their phases, composition (via X-ray diffraction (XRD)), and particle size. Alternatively, sodium borohydride can be replace with activated alkaline metal reducing agents as indicated below:

SiCl₄+4Na→nano-Si+4NaCl 3)

GeCl₄+4Na→nano-Ge+4NaCl 4)

In some embodiments, alloys are generated by co-reduction of the metal salts with NaBH₄ or alkaline metal, as indicated below:

4SiCl₄+GeCl₄+20NaBH→nano-Si₄Ge(=Si_{0.8}Ge_{0.2})+10H₂+10B₂H₆+20NaCl 5)

4SiCl₄+GeCl₄+20Na→nano-Si₄Ge(=Si_{0.8}Ge_{0.2})+20NaCl 6)

N-doping can be achieved by adding and reducing the proper amount of PCl₃ or PCl₅ in the same manner. Concentrations of dopants and any gradients can be accommodated for optimized performance by separate synthesis using varied concentrations of reagents in batches.

A variety of different surfactants can be used to produce small nanoparticle sizes and narrow size distribution. In some embodiments, the surfactants include long chain amines, such as dodecyl amine. Long chain amines can be volatile enough to evaporate during compaction. In some embodiments, a lower volatility surfactant can be provided after nanoparticle growth by ligand exchange. Such an exchange can be carried out by stirring the nanoparticles in a solution rich in lower volatility surfactants.

The p-type material used in the fabrication of highly doped and undoped B₄C nanoparticles as well as hetero-nanoparticles with higher mass can be carried out in a similar manner. For example, undoped B₄C preparation can be accomplished by reducing precursors like BCl₃ and C₂Cl₄ as shown below:

BCl₃+3Na→nano-B+3NaCl 7)

C₂Cl₄+4Na→nano-C₂+4NaCl 8)

The obtained nanoparticles can be analyzed in the same manner as the silicon germanium alloy described above. The requisite carbide can be formed by co-reduction as described above and shown below:

8BCl₃+C₂Cl₄+28Na→nano-B₄C+28NaCl 9)

P-doping of B₄C can be achieved by adding the proper amount of carbon (C) in the reduction step. A variety of different surfactants can be employed to produce the smallest sizes and narrow size distribution as outlined above.

In order to most effectively scatter mid- and long-wave phonons the addition of a small amount, such as between about 0.5 to about 2% w/w, of hetero-nanoparticles can be employed. In the case of silicon germanium alloys, silicide nanoparticles of heavy transition metals, such as tungsten (W) or lanthanide metals such as Ce can be prepared, as described herein above. WSi₂ and CeSi₂ are readily prepared in the line with the metal reduction approach described above and shown below for the requisite silicides:

WCl₆+2SiCl₄+14NaBH₄→nano-WSi₂+14NaCl+7H₂+7B₂H₆ 10)

Ce(NO₃)₄+2SiCl₄+12Na→nano-CeSi₂+4NaNO₃+8NaCl 11)

Because metal nanoparticles are reactive and oxidize immediately upon contact with moisture and air-oxygen, the cerium precursor can be dried. One approach to drying is the in situ drying of the salt as shown below employing an orthoester:

Ce(NO₃)₃6H₂O+2HC(OCH₃)₃→Ce(NO₃)₃+2HC(O)OCH₃+4CH₃OH 12)

Ce(NO₃)₃2H₂O+2(CH₃)₂C(OCH₃)₃→Ce(NO₃)₃+2CH₃C(O)CH₃+4CH₃OH 13)

As described above, when employing a p-type B₄C, the hetero-nanoparticles can include the exemplary SiC or WC, which can be prepared by similar reduction processes as shown below:

2SiCl₄+C₂Cl₄+12Na→2nano-SiC+12NaCl 14)

2WCl₆+C₂Cl₄+16Na→2WC+16NaCl 15)

One skilled in the art will recognize that all the aforementioned borohydride and/or metal-based reductions provided by equations 1-15 above are carried out with appropriate surfactants to control nanoparticle growth.

Once de novo preparation of the requisite nanoparticles is complete, methods of the invention proceed to the formation of a high performance thermoelectric material by way of nanoparticle compaction to produce fully dense materials. To minimize thermal conductivity, it is desirable to preserve the original nanostructure of the starting material because of the maximized phonon scattering provided by the nanostructure. High densities are desired because porosity reduces the electrical conductivity thereby resulting in a reduced power factor (S².φ). The compaction process for the manufacture of composites of the invention utilize high current fluxes that result in very high heating rates (>1000° C./min), with good temperature homogeneity throughout the sample, allowing for uniform compaction to occur very rapidly and to full density with minimal grain growth. This is difficult to achieve using standard hot-pressing techniques which lead to significant grain growth and higher porosities. Current-activated pressure assisted densification (CAPAD) has proven effective in significantly lowering the processing temperature and time required for consolidating composite materials to full density. The process provides additional benefits such as plasma formation in the inter-powder regions, current enhanced mass transport and reactivity decreasing defect mobility energy by as much as 24% under exposure to current. The applied moderate pressure aids the densification process by increasing the surface energy driving force, which is beneficial for consolidating nanoparticles.

The description of the invention is provided to enable any person skilled in the art to practice the various embodiments described herein. While the present invention has been particularly described with reference to the various figures and embodiments, it should be understood that these are for illustration purposes only and should not be taken as limiting the scope of the invention.

There may be many other ways to implement the invention. Various functions and elements described herein may be partitioned differently from those shown without departing from the spirit and scope of the invention. Various modifications to these embodiments will be readily apparent to those skilled in the art, and generic principles defined herein may be applied to other embodiments. Thus, many changes and modifications may be made to the invention, by one having ordinary skill in the art, without departing from the spirit and scope of the invention.

A reference to an element in the singular is not intended to mean “one and only one” unless specifically stated, but rather “one or more.” The term “some” refers to one or more. Underlined and/or italicized headings and subheadings are used for convenience only, do not limit the invention, and are not referred to in connection with the interpretation of the description of the invention. All structural and functional equivalents to the elements of the various embodiments described throughout this disclosure that are known or later come to be known to those of ordinary skill in the art are expressly incorporated herein by reference and intended to be encompassed by the invention. Moreover, nothing disclosed herein is intended to be dedicated to the public regardless of whether such disclosure is explicitly recited in the above description.

What is claimed is:

1. A composite comprising:
a matrix comprising a plurality of matrix nanoparticles; and
a plurality of hetero-nanoparticles, said plurality of hetero-nanoparticles being dispersed in said matrix, said plurality of hetero-nanoparticles comprising an atom having an atomic weight larger than the atoms in said plurality of matrix nanoparticles.

2. The composite of claim 1, wherein said composite is capable of scattering short, medium, and long wave phonons.

3. The composite of claim 1, wherein said composite has a thermoelectric figure of merit (ZT) in a range between about 1 to about 5.

4. The composite of claim 1, wherein said composite has a ZT in a range from between about 2 to about 5.

5. The composite of claim 1, wherein said composite has a ZT of at least 5.

6. The composite of claim 1, wherein said composite has a ZT in a range from between about 5 to about 10.

7. The composite of claim 1, wherein said matrix nanoparticles range in size from between about 5 nm to about 10 nm.

8. The composite of claim 1, wherein said plurality of hetero-nanoparticles range in size from between about 10 nm to about 20 nm.

9. The composite of claim 1, wherein said plurality of hetero-nanoparticles range in size from between about 20 nm to about 30 nm.

10. The composite of claim 1, wherein said plurality of hetero-nanoparticles range in size from between about 30 nm to about 50 nm.

11. The composite of claim 1, wherein said plurality of hetero-nanoparticles range in size from between about 50 nm to about 100 nm.

12. The composite of claim 1, wherein said plurality of hetero-nanoparticles are dispersed uniformly throughout said matrix.

13. The composite of claim 1, wherein said plurality of hetero-nanoparticles are dispersed in a gradient concentration in said matrix.

14. The composite of claim 1, wherein said plurality of hetero-nanoparticles are dispersed to form a functionally graded material.

15. The composite of claim 1, wherein said matrix nanoparticles comprise silicon and carbon.

16. The composite of claim 1, wherein said matrix nanoparticles comprise silicon and germanium.

17. The composite of claim 16, wherein said matrix nanoparticles comprise Si_{0.8}Ge_{0.2}.

18. The composite of claim 16, further comprising n-type doping particles.

19. The composite of claim 18, wherein said n-type doping particles are selected from the group consisting of phosphorus, antimony, bismuth, silicon fluoride, silicon oxide, germanium fluoride, and germanium oxide.

20. The composite of claim 16, further comprising p-type doping particles.

21. The composite of claim 20, wherein said p-type doping particles comprise boron, aluminum, gallium, indium, iron, manganese, zink, magnesium, calcium, strontium, barium.

22. The composite of claim 16, wherein said plurality of hetero-nanoparticles is selected from the group consisting of tungsten silicide, cerium silicide, tungsten germanide, cerium germanide, iron, molybdenum, manganese, chromium silicide and germanide and combinations thereof.

23. The composite of claim 1, wherein said matrix nanoparticles comprise boron and carbon.

24. The composite of claim 23, wherein said matrix nanoparticles comprise B₃C, B₄C, B₅C or combinations thereof.

25. The composite of claim 23, wherein said plurality of hetero-nanoparticles is selected from the group consisting of silicon carbide, tungsten carbide, silicon boride, tungsten boride, iron, molybdenum, manganese, chromium boride and carbide and combinations thereof.

26. The composite of claim 1, wherein said hetero nanoparticles are present in a concentration ranging from between about 1 to about 10 percent.

27. The composite of claim 1, wherein said hetero nanoparticles are present in a concentration ranging from between about 2 to about 8 percent.

28. The composite of claim 1, wherein said hetero nanoparticles are present in a concentration ranging from between about 3 to about 6 percent.

29. The composite of claim 1, wherein said matrix nanoparticles are doped to the level of 10¹⁹ to 10²⁵.

30. A thermoelectric converter comprising:
one or more first legs, each comprising an n-doped composite, said n-doped composite comprising:
a first matrix comprising a first plurality of matrix nanoparticles; and
a first plurality of hetero-nanoparticles, said first plurality of hetero-nanoparticles being dispersed in said first matrix, said first plurality of hetero-nanoparticles comprising an atom having an atomic weight larger than the atoms in said first plurality of matrix nanoparticles; and
one or more second legs, each comprising a p-doped composite, said p-doped composite comprising:
a second matrix comprising a second plurality of matrix nanoparticles; and
a second plurality of hetero-nanoparticles, said second plurality of hetero-nanoparticles being dispersed in said second matrix, said second plurality of hetero-nanoparticles comprising an atom having an atomic weight larger than the atoms in said second plurality of matrix nanoparticles.

31. The thermoelectric converter of claim 30, wherein said n-doped composite and said p-doped composite are capable of scattering short, medium, and long wave phonons.

32. The thermoelectric converter of claim 30, wherein said n-doped composite and said p-doped composite have a thermoelectric figure of merit (ZT) in a range between about 1 to about 5.

33. The thermoelectric converter of claim 32, wherein said n-doped composite and said p-doped composite have a ZT in a range from between about 2 to about 5.

34. The thermoelectric converter of claim 30, wherein said n-doped composite and said p-doped composite have a ZT of at least 5.

35. The thermoelectric converter of claim 30, said converter having an efficiency in a range from between about 20% to about 30%.

36. The thermoelectric converter of claim 30, further comprising a platform on which said one or more first legs and said one or more second legs are disposed, wherein said one or more first legs and said one or more second legs are electrically insulated from each other.

37. The thermoelectric converter of claim 30, further comprising a plate equipped with electrical contacts, said contacts operably-linked to said one or more first legs and said one or more second legs; said plate being distal to said platform.

38. The thermoelectric converter of claim 30, wherein said thermoelectric converter is capable of operating at an upper temperature limit ranging from between about 600° C. to about 900° C.

39. A method of making a composite for thermoelectric converter applications comprising providing a mixture a plurality of matrix nanoparticles and a plurality of hetero-nanoparticles and applying current activated pressure assisted densification or spark plasma sintering to form said composite.
